(19) United States
(12) Patent Application Publication
(10) Pub. No.: US 2022/0219028 A1
(43) Pub. Date: Jul. 14, 2022

(54) CONTAINER FOR STORING A MOBILE DEVICE WHILE RECHARGING

(71) Applicant: Olav Asserson, SANDNES (NO)

(72) Inventor: Olav Asserson, SANDNES (NO)

(21) Appl. No.: 17/607,246

(22) PCT Filed: May 14, 2020
(86) PCT No.: PCT/NO2020/050123

§ 371 Date: Oct. 28, 2021

(30) Foreign Application Priority Data
May 21, 2019 (NO) 2019 0634

(51) Int. Cl. A62C 2/18; H02J 7/00; H02H 7/18; A62C 3/16; A62C 37/40

(52) U.S. Cl. CPC A62C 2/18; H02J 7/0044; G08B 17/00; A62C 3/16; A62C 37/40; H02H 7/18

(57) ABSTRACT

A container is for storing at least one mobile device being recharged. The container has a self-closing door for closing the container, a sensor for detecting a fire inside the container, and an actuator for retaining the door in an open position. The actuator is adaptable to release the door when a fire is detected by the sensor. A mobile device may thus be safely recharged while its user is unaware or asleep.

### CROSS-REFERENCE TO RELATED APPLICATIONS

This application is the U.S. national stage application of International Application PCT/NO2020/050123, filed May 14, 2020, which international application was published on Nov. 26, 2020, as International Publication WO 2020/236005 in the English language. The International Application claims priority of Norwegian Patent Application No. 20190634, filed May 21, 2019. The international application and Norwegian application are both incorporated herein by reference, in entirety.

### FIELD

The present invention relates to a container for storing at least one mobile device while recharging.

### BACKGROUND

A significant amount of house fires is caused by electrical systems and apparatuses. For example, according to the Norwegian Fire Protection Association (Norsk brannvernforening), approximately 50% of all house fires are caused by these sources.

In particular, many house fires are started by electric chargers that were recharging a mobile device, such as a mobile phone or a tablet, when the fire started. It is common knowledge that the chargers of mobile devices generate heat during recharging operations and in some instances can start a fire. This can be caused by product failures, user failures or damages to devices and/or charging equipment.

Moreover, electric chargers are often left recharging a mobile device while the user is unaware or asleep. For example, as many as 7 of 10 Norwegians choose to charge their mobile devices at night, according to a survey carried out by a Norwegian insurance company (If Skadeforsikring), the Directorate for Norwegian Civil Security and Emergency Planning, and the Norwegian Fire Protection Association. A fire that starts at night while people are sleeping or unaware can have fatal consequences.

Document CN 107856554 A discloses a battery safety charging storage cabinet and a self-charging method aiming at improving battery charging and storage safety, anti-theft and convenience of charging. Upon detecting smoke or high temperature, an alarm device sends an alarm to the surroundings using sound and light.

Document CN 206922443 U discloses a charging bin compartment for charging of rechargeable batteries used in various electronic products. When a smoke detector detects smoke, the power supply is shutdown and a fire extinguisher is turned on.

Thus, it can be challenging to recharge a mobile device safely while a user is unaware or asleep.

### SUMMARY

The present invention will now be disclosed.

According to a first aspect of the present invention, there is provided a container for storing at least one mobile device being recharged, the container comprising:
a self-closing door for closing the container;
a sensor for detecting a fire inside the container; and
an actuator for retaining the door in an open position,

wherein the actuator is adaptable to release the door when a fire is detected by the sensor.

It has been realised that, by providing the self-closing door closing the container when a fire is detected, a mobile device may be safely recharged while still being easily accessible to the user by direct contact. When a fire is detected, a full barrier is created to separate the interior and the exterior of the container. Thus, the container effectively provides a fire protection system that actuates in the initial stage of a fire when there is still a low amount of flames to extinguish.

The actuator may be connectable to a power source for recharging the at least one mobile device. Also, the power source may be adaptable to be switched off when a fire is detected by the sensor. These embodiments have the advantage that both the position of the door and the power supply are synchronously changed when the power source is turned off. Thus, an improved fire extinguishing action is achieved by the synchronous actuation of both the closing of the door and the switching off of the power supply.

The container may include a wireless communication module for communicating with a wireless circuit breaker when a fire is detected by the sensor. Also, the wireless circuit breaker may be adapted to switch the power source on or off. Moreover, the wireless communication module may be configured to communicate with a fire alarm system.

The self-closing door may be self-closing due to gravity, which has the advantage of achieving a simple design. Alternatively, the self-closing door may be self-closing due a spring. This embodiment is advantageous in that a more energy efficient actuator may be provided to retain the door in an open position. Also, the self-closing door may be self-closing due both gravity and a spring. This combination achieves an improved closing speed of the door, and this improves the actuation to extinguish a fire in the container.

The actuator for retaining the door in an open position may be a fail-safe electromagnetic lock. This fail-safe locking device unlocks when de-energized, and this thus has the advantage that the door closes in case of a power outage; in other words, the door is fail-safe, in that the door self-closes when the electric power to keep it open fails. This makes the container's safety exist even when there is no power. A power outage may occur due to a short circuit while a mobile device was recharging, and this allows actuating in a pre-emptive manner, even before a fire has started.

The container may also include a fire extinguisher for releasing an extinguishing agent inside the container when a fire is detected by the sensor. The extinguishing agent may be CO2 or a foam. This achieves an improved actuation when a fire is detected. The combination of releasing the extinguishing agent in combination with the actuation of the self-closing door achieves a further improved fire extinguishing action.

The container may contain a sound alarm for producing an audible sound when a fire is detected by the sensor. Also, the sensor may be any of a heat sensor, a smoke sensor or a flame sensor.

### BRIEF DESCRIPTION OF THE DRAWINGS

Embodiments of the invention will now be described, by way of example only, with reference to the accompanying drawings, in which:

FIGS. 1A, 1B, 1C are perspective and elevation schematic views of a first container embodiment, in which the container includes a door that is self-closing due to gravity;

FIG. 2 is a perspective schematic view of a second container embodiment, in which the container includes a door that is self-closing due to a spring.

FIG. 3 is a perspective schematic view of a third container embodiment, in which the container includes a door that is self-closing due to gravity and a spring.

### DETAILED DESCRIPTION OF THE DRAWINGS

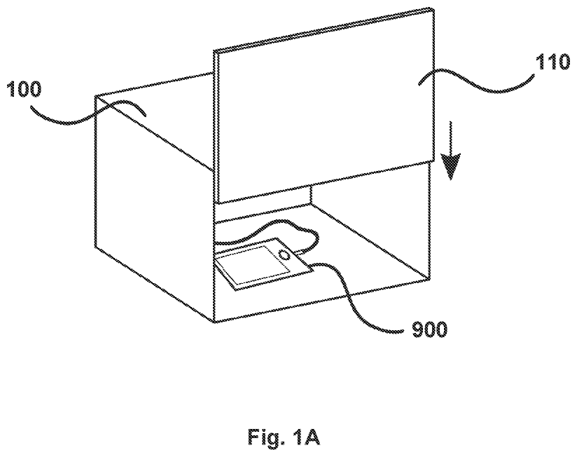

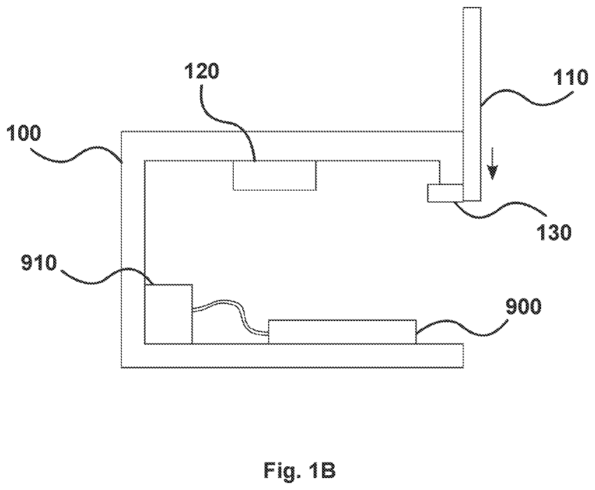

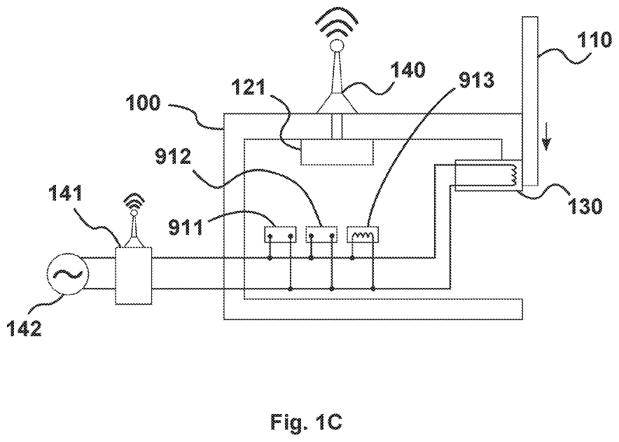

Turning now to FIG. 1A, it shows a perspective view of a container 100 embodiment including a self-closing door 110. In the situation being shown, a mobile device 900 is recharging inside the container 100. For illustrative purposes, the internal components of the container 100 are not shown in FIG. 1A.

Although the mobile device 900 shown in FIG. 1A resembles a tablet or a smartphone, the mobile device 900 may be any item including a rechargeable battery, such as a laptop, a flashlight, a wireless power tool, or a rechargeable battery itself. The container 100 may be implemented with different sizes and forms so that different items may be placed inside the container 100.

The user of the mobile device 900 can leave the latter recharging inside the container 100 without having to be aware or awake and to monitor if the recharging operation is happening safely without starting a fire. The device is directly accessible while the recharging operation is taking place, as is observable in FIG. 1A.

When a safety event, such as a fire, is detected inside the container, the door 110 will close the container in a descending vertical movement, as shown by the arrow in FIG. 1A. The container 100 is made of material suitable for heat and small fire. Thus, the fire will be enclosed in the container 100 and its risk of propagation will be efficiently attacked at its early stages.

FIG. 1B shows an elevation view of the container 100 shown in FIG. 1A. Both the mobile device 900 and the charger 910 are shown inside the container 100. In addition to the self-closing door 110, the container 100 includes a sensor 120 for detecting a fire inside the container 100 and an actuator 130 for retaining the door 110 in the open position (as shown in FIG. 1B).

The sensor 120 is positioned on the ceiling of the interior of the container 100, above where electronic equipment, such as the mobile device 900, is expected to be recharging. It is also suitable to have the sensor in any other position that allows detecting fire in the interior of the container 100. If any safety event happens, such as the mobile device 900 or the charger 910 starting a fire, the sensor 120 will detect it.

Several options may be chosen for implementing the sensor 120, such as a heat sensor, fire sensor, or a flame sensor.

The door 110 is retained in the open position by the actuator 130. One option for implementing the actuator 130 is to use a magnetic actuator that produces a magnetic force in a portion of the door 110 and will thus keep the door fixed in the open position. Another option is for the actuator 130 to grip the surface of the door 110 with an appropriate contact surface.

When the sensor 120 detects a safety event, the power signal of the actuator will be switched off so that the door 110 is released. This reacting control of the actuator 130 may be implemented in many manners known by a skilled person.

FIG. 1C shows a schematic elevation view of the container 100 embodiment including some additional components: three charging points 911, 912, 913 are shown inside the container 100; and the sensor 121 includes a wireless communication module 140. Also shown is a schematic of the electric circuit that powers the three charging points 911, 912, 913 and the actuator 130 for retaining the door. This schematic also includes a representation of the power source 142 from which electric power is drawn and a wireless circuit break 141 for switching the power source 142 on or off.

The three charging points include a mains socket 911, a USB female socket 912, and a wireless charger 913. Also, the actuator 130 is powered to the same electric circuit of the charging points 911, 912, 913. This enables a global fail-safe capability, in which the switching off of the power supply applies directly to all the charging points 911, 912, 913 and also the actuator 130.

When the sensor 121 detects a fire, the wireless communication module 140 is used for communicating this to the wireless circuit breaker 141. This communication can be implemented with a Wireless Z-wave signal platform with 868.4 MHz RF (908.4 MHz USA/Canada), for example. The wireless circuit breaker 141 therefore cuts the power being supplied to the container 100. This achieves an improved actuation when a fire is detected, as switching off the power supply of the container results in both the charging points 911, 912, 913 being switched off as well as the door 110 closing. Therefore, and improved efficiency is achieved in attacking a fire in its early stages.

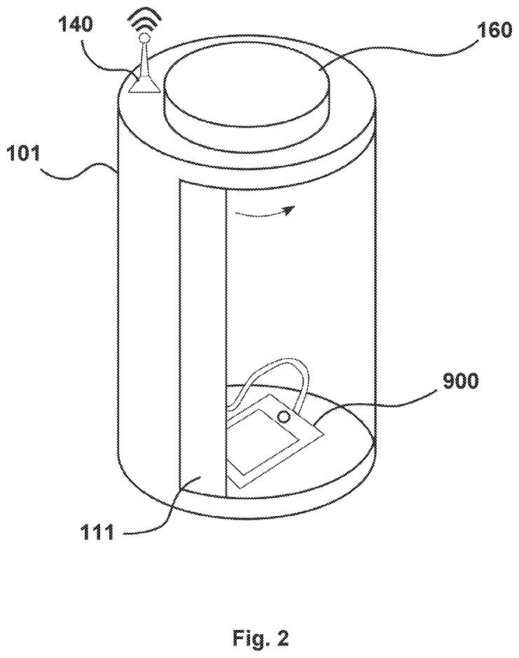

FIG. 2 shows a perspective view of a second container 101 embodiment, in which the container 101 includes a door 111 that is self-closing due to a spring (not shown). The container 101 has a cylindrical form and the door 111 closes in a horizontal motion similar to the motion of a curtain closing.

For illustrative purposes, the container 101 is shown from a global point of view from the outside and both the actuator and the sensor are not shown. The actuator is positioned on the inside of the container and operates to retain the door 111 in the open position shown in FIG. 2. The sensor is on a portion of the interior of the container 101 that is suitable for detecting fire from a mobile device recharging inside the container 101. For example, the sensor may be positioned on the ceiling or upper part of the interior of the container 101. The cylindrical form in combination with the position of the sensor on the upper part of the interior of the container 101 provides an improved detection of fire or any other safety events inside the container, as the sensor can thus perform isotropic measurements.

The container 101 also includes an audio alarm 160 at the top, which produces an audible sound when a fire is detected by the sensor. This is increases the container's safety in fighting fire, as it will give its user a warning that a safety event has been detected.

Moreover, the container 101 includes a wireless communication module 140 similar to the one shown in FIG. 1C, although in this case the wireless communication module 140 is further used to communicate with a fire alarm system, which may have further configurations to immediately issue an emergency request to the emergency services or the local fire department.

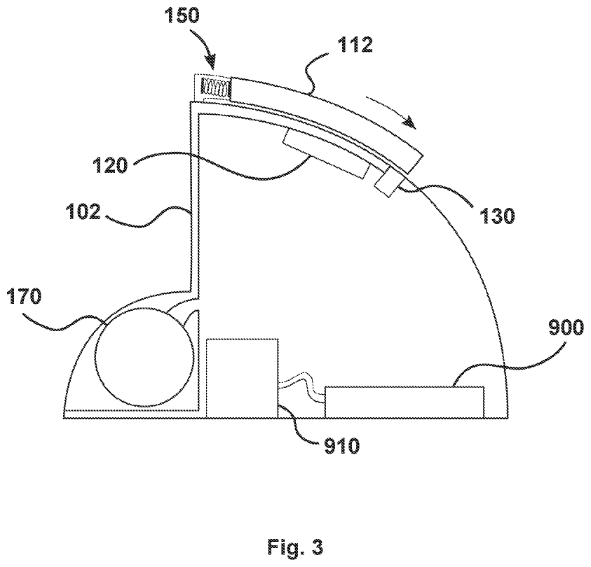

In FIG. 3, an elevation view of a third container 102 embodiment is shown. The container 102 includes two compartments: a first compartment is shown on the centre and right half of FIG. 3, and it includes a housing for positioning a mobile device 900 to be recharged; a second compartment is shown on the lower portion of the left half of FIG. 3, in which a fire extinguisher 170 is shown.

The first compartment includes a self-closing door 112 that self-closes in a semi-circular sliding motion on the first compartment (see arrow near the door 112 in FIG. 3). The door 112 is self-closing due gravity and a spring 150. This combination produces an efficient closing movement, and this gives an improved action to close the interior of the container and stop any mobile device or charger fire from evolving into a stronger fire.

The second compartment includes the fire extinguisher 170 for further increasing the extinguishing actuation in the first compartment when a fire is detected by sensor 120. The first and second compartments are connected by a channel that enables the fire extinguisher 170 to dispense an extinguishing agent into the first compartment, such as foam or CO₂.

Generally, the terms used in this description and claims are interpreted according to their ordinary meaning the technical field, unless explicitly defined otherwise. Notwithstanding, the terms “comprises” and “comprising” and variations thereof mean that the specified features, steps or integers are included. These terms are not interpreted to exclude the presence of other features, steps or integers. Furthermore, the indefinite article “a” or “an” is interpreted openly as introducing at least one instance of an entity, unless explicitly stated otherwise. An entity introduced by an indefinite article is not excluded from being interpreted as a plurality of the entity.

The features disclosed in the foregoing description, or in the following claims, or in the accompanying drawings, expressed in their specific forms or in terms of a means for performing the disclosed function, or a method or process for obtaining the disclosed results, as appropriate, may, separately, or in any combination of such features, be utilised for realising the invention in diverse forms thereof.

While the invention has been described in conjunction with the embodiments described above, many equivalent modifications and variations will be apparent to those skilled in the art when given this disclosure. Accordingly, the embodiments of the invention set forth above are considered to be illustrative and not limiting. Various changes to the described embodiments may be made without departing from the spirit and scope of the invention.

### REFERENCE NUMBERS

100, 101, 102—container
110, 111, 112—self-closing door
120, 121—sensor
130—actuator
140—wireless communication module
141—wireless circuit breaker
142—power source
150—spring
160—sound alarm
170—fire extinguisher
900—mobile device
910—electric charger
911, 912, 913—charging points

1. A container for storing at least one mobile device being recharged, the container comprising:
a self-closing door for closing the container;
a sensor for detecting a fire inside the container; and
an actuator for retaining the door in an open position,
wherein the actuator is adaptable to release the door when a fire is detected by the sensor.

2. The container according to claim 1, wherein the actuator is connectable to a power source for recharging the at least one mobile device.

3. The container according to claim 2, wherein the power source is adaptable to be switched off when a fire is detected by the sensor.

4. The container according to claim 1, comprising a wireless communication module for communicating with a wireless circuit breaker when a fire is detected by the sensor.

5. The container according to claim 2, wherein the wireless circuit breaker is adapted to switch the power source on or off.

6. The container according to claim 4, wherein the wireless communication module is configured to communicate with a fire alarm system.

7. The container according to claim 1, wherein the self-closing door is self-closing due to gravity and/or a spring.

8. The container according to claim 1, wherein the actuator for retaining the door in an open position is a fail-safe electromagnetic lock.

9. The container according to claim 1, comprising a fire extinguisher for releasing an extinguishing agent inside the container when a fire is detected by the sensor.

10. The container according to claim 9, wherein the extinguishing agent is CO2 or a foam.

11. The container according to claim 1, comprising a sound alarm for producing an audible sound when a fire is detected by the sensor.

12. The container according to claim 1, wherein the sensor is any of a heat sensor, a smoke sensor or a flame sensor.

13. The container according to claim 3, wherein the wireless circuit breaker is adapted to switch the power source on or off.

14. The container according to claim 4, wherein the wireless circuit breaker is adapted to switch the power source on or off.

15. The container according to claim 5, wherein the wireless communication module is configured to communicate with a fire alarm system.
